(19) United States
(12) Patent Application Publication
(10) Pub. No.: US 2023/0073527 A1
(43) Pub. Date: Mar. 9, 2023

(54) SENSOR PACKAGE STRUCTURE AND MANUFACTURING METHOD THEREOF

(71) Applicant: KINGPAK TECHNOLOGY INC., Hsin-Chu County (TW)

(72) Inventors: CHIEN-YUAN WANG, Hsin-Chu County (TW); CHIEN-CHEN LEE, Hsin-Chu County (TW)

(21) Appl. No.: 17/564,142

(22) Filed: Dec. 28, 2021

(30) Foreign Application Priority Data
Sep. 9, 2021 (TW) 110133494

(51) Int. Cl. H01L 27/146

(52) U.S. Cl. CPC H01L 27/14623; H01L 27/14618; H01L 27/14636; H01L 27/14685

(57) ABSTRACT

A sensor package structure and a manufacturing method thereof are provided. The sensor package structure includes a substrate, a sensor chip, and a cover. The sensor chip is disposed on and electrically coupled to the substrate. The cover is disposed on the substrate along an assembling direction, so that the sensor chip is arranged in a space surroundingly defined by the cover. The cover includes a light-permeable sheet, a light-shielding film, and an opaque frame. The light-shielding film is ring-shaped and is disposed on an inner surface of the light-permeable sheet, so as to divide the inner surface into a light-permeable region arranged inside of the light-shielding film and a formation region arranged outside of the light-shielding film The opaque frame is gaplessly formed on the formation region and is disposed on the substrate, and the opaque frame does not cover the light-shielding film.

### CROSS-REFERENCE TO RELATED PATENT APPLICATION

This application claims the benefit of priority to Taiwan Patent Application No. 110133494, filed on Sep. 9, 2021. The entire content of the above identified application is incorporated herein by reference.

Some references, which may include patents, patent applications and various publications, may be cited and discussed in the description of this disclosure. The citation and/or discussion of such references is provided merely to clarify the description of the present disclosure and is not an admission that any such reference is “prior art” to the disclosure described herein. All references cited and discussed in this specification are incorporated herein by reference in their entireties and to the same extent as if each reference was individually incorporated by reference.

### FIELD OF THE DISCLOSURE

The present disclosure relates to a package structure, and more particularly to a sensor package structure and a manufacturing method thereof.

### BACKGROUND OF THE DISCLOSURE

A conventional sensor package structure is provided by placing a glass board onto a sensor chip through a glue layer that surrounds an outer periphery of a sensing region of the sensor chip. However, light passing through the glass board may be partially reflected by the glue layer, thereby affecting the sensing region of the sensor chip (e.g., a flare issue may occur in the sensing region).

### SUMMARY OF THE DISCLOSURE

In response to the above-referenced technical inadequacy, the present disclosure provides a sensor package structure and a manufacturing method thereof to effectively improve on the issues associated with conventional sensor package structures.

In one aspect, the present disclosure provides a sensor package structure, which includes a substrate, a sensor chip, and a cover. The sensor chip is disposed on and electrically coupled to the substrate. The cover is disposed on the substrate. The sensor chip is arranged in a space surroundingly defined by the cover, and the cover includes a light-permeable sheet, a light-shielding film, and an opaque frame. The light-permeable sheet has an outer surface and an inner surface. The light-shielding film is in a ring-shape and is disposed on the inner surface, so that the inner surface is divided into a light-permeable region that is arranged inside of the light-shielding film and a formation region that is arranged outside of the light-shielding film. The opaque frame is gaplessly formed on the formation region and is disposed on the substrate. The light-shielding film is not embedded in the opaque frame.

In another aspect, the present disclosure provides a manufacturing method of a sensor package structure, which includes: implementing a delimiting step by forming a plurality of light-shielding films that are spaced apart from each other on an inner surface of a light-permeable layer so as to divide the inner surface of the light-permeable layer into a plurality of light-permeable regions respectively arranged inside of the light-shielding films, and a formation region that is arranged outside of the light-shielding films; implementing a molding step by using a mold to gaplessly press onto the light-shielding films, and then forming an opaque frame layer on the formation region of the light-permeable layer; implementing a pre-cutting step by cutting the light-permeable layer and the opaque frame layer, so as to form a plurality of covers; implementing an encapsulating step by placing the covers onto a substrate layer that carries a plurality of sensor chips, in which each of the covers encloses one of the sensor chips therein, and each of the light-permeable regions faces toward one of the sensor chips; and implementing a cutting step by cutting the substrate layer, so as to form multiple ones of the sensor package structure.

In yet another aspect, the present disclosure provides a manufacturing method of a sensor package structure, which includes: implementing a delimiting step by forming a plurality of light-shielding films that are spaced apart from each other on an inner surface of a light-permeable layer so as to divide the inner surface of the light-permeable layer into a plurality of light-permeable regions respectively arranged inside of the light-shielding films, and a formation region that is arranged outside of the light-shielding films; implementing a molding step by using a mold to gaplessly press onto the light-shielding films, and then forming an opaque frame layer on the formation region of the light-permeable layer; implementing an encapsulating step by placing the opaque frame layer onto a substrate layer that carries a plurality of sensor chips, in which each of the light-permeable regions faces toward one of the sensor chips; and implementing a cutting step by cutting the light-permeable layer, the opaque frame layer, and the substrate layer, so as to form multiple ones of the sensor package structure.

Therefore, in the sensor package structure and the manufacturing method thereof provided by the present disclosure, the light-shielding film is formed on the inner surface of the light-permeable sheet. In this way, the light-permeable region of the inner surface can be precisely defined, and external light can be effectively prevented from passing through the light-shielding film, so as to reduce occurrences of a flare issue. Moreover, during formation of the opaque frame, the light-shielding film can prevent the opaque frame from flowing toward the light-permeable region, so that the opaque frame can be precisely formed on the formation region.

These and other aspects of the present disclosure will become apparent from the following description of the embodiment taken in conjunction with the following drawings and their captions, although variations and modifications therein may be affected without departing from the spirit and scope of the novel concepts of the disclosure.

### BRIEF DESCRIPTION OF THE DRAWINGS

The described embodiments may be better understood by reference to the following description and the accompanying drawings, in which:

FIG. 1 is a perspective view of a sensor package structure according to a first embodiment of the present disclosure;

FIG. 2 is a top view of FIG. 1;

FIG. 3 is a cross-sectional view taken along line III-III of FIG. 2;

FIG. 4 is a schematic view showing a delimiting step of a manufacturing method of the sensor package structure according to the first embodiment of the present disclosure;

FIG. 5A and FIG. 5B are schematic views showing a molding step of the manufacturing method of the sensor package structure according to the first embodiment of the present disclosure;

FIG. 6 is a schematic view showing a pre-cutting step of the manufacturing method of the sensor package structure according to the first embodiment of the present disclosure;

FIG. 7 is a schematic view showing an encapsulating step of the manufacturing method of the sensor package structure according to the first embodiment of the present disclosure;

FIG. 8 is a schematic view showing a cutting step of the manufacturing method of the sensor package structure according to the first embodiment of the present disclosure;

FIG. 9 is a schematic view showing the encapsulating step of the manufacturing method of the sensor package structure according to a second embodiment of the present disclosure; and

FIG. 10 is a schematic view showing the cutting step of the manufacturing method of the sensor package structure according to the second embodiment of the present disclosure.

### DETAILED DESCRIPTION OF THE EXEMPLARY EMBODIMENTS

The present disclosure is more particularly described in the following examples that are intended as illustrative only since numerous modifications and variations therein will be apparent to those skilled in the art. Like numbers in the drawings indicate like components throughout the views. As used in the description herein and throughout the claims that follow, unless the context clearly dictates otherwise, the meaning of “a”, “an”, and “the” includes plural reference, and the meaning of “in” includes “in” and “on”. Titles or subtitles can be used herein for the convenience of a reader, which shall have no influence on the scope of the present disclosure.

The terms used herein generally have their ordinary meanings in the art. In the case of conflict, the present document, including any definitions given herein, will prevail. The same thing can be expressed in more than one way. Alternative language and synonyms can be used for any term(s) discussed herein, and no special significance is to be placed upon whether a term is elaborated or discussed herein. A recital of one or more synonyms does not exclude the use of other synonyms. The use of examples anywhere in this specification including examples of any terms is illustrative only, and in no way limits the scope and meaning of the present disclosure or of any exemplified term. Likewise, the present disclosure is not limited to various embodiments given herein. Numbering terms such as “first”, “second” or “third” can be used to describe various components, signals or the like, which are for distinguishing one component/signal from another one only, and are not intended to, nor should be construed to impose any substantive limitations on the components, signals or the like.

### First Embodiment

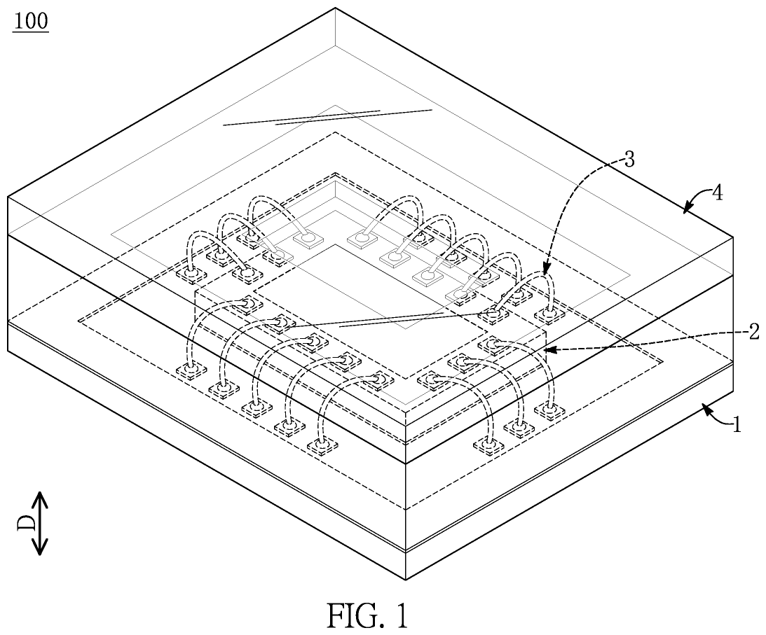

Referring to FIG. 1 to FIG. 8, a first embodiment of the present disclosure provides a sensor package structure 100 and a manufacturing method thereof. In order to clearly describe the present embodiment, the following description describes the structure and connection relationship of each component of the sensor package structure 100, and then describes the manufacturing method of the sensor package structure 100.

As shown in FIG. 1 to FIG. 3, the sensor package structure 100 in the present embodiment includes a substrate 1, a sensor chip 2 disposed on the substrate 1, a plurality of wires 3 electrically coupling the sensor chip 2 to the substrate 1, and a cover 4 that is disposed on the substrate 1.

It should be noted that the sensor package structure 100 in the present embodiment includes the above components, but can be adjusted or changed according to design requirements. For example, in other embodiments of the present disclosure not shown in the drawings, the sensor package structure 100 can be provided without the wires 3, and the sensor chip 2 is fixed and electrically coupled to the substrate 1 in a flip-chip mariner.

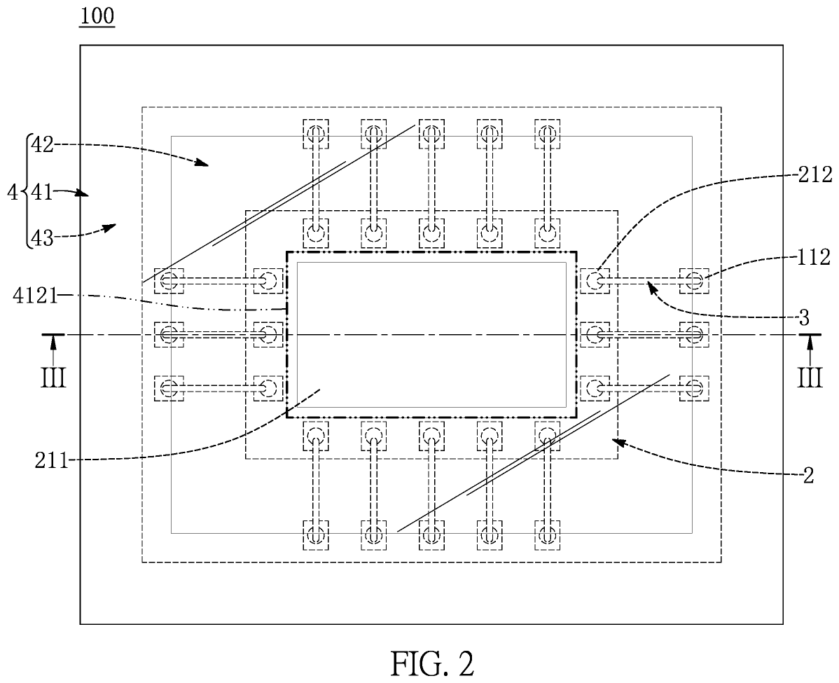

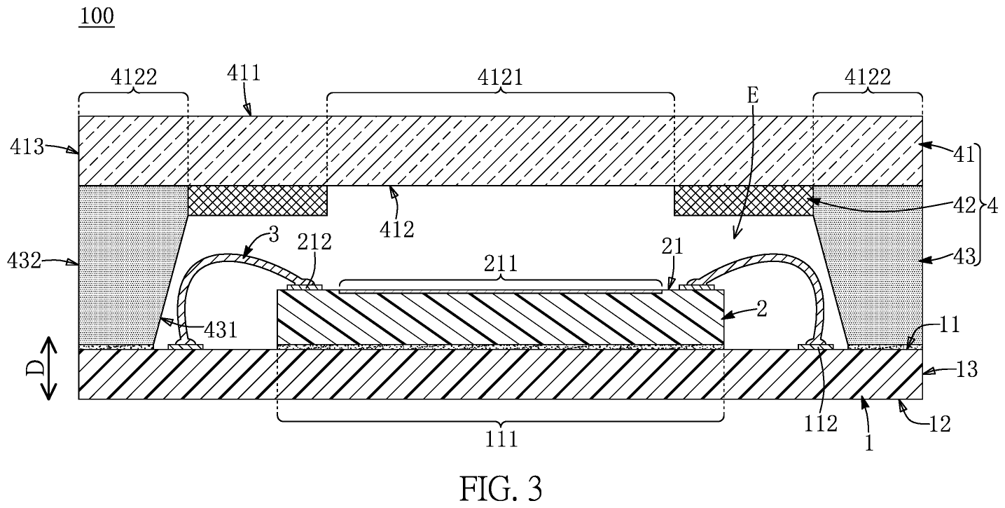

As shown in FIG. 2 and FIG. 3, the substrate 1 of the present embodiment is a square-shaped printed circuit board (PCB) or a rectangular PCB, but the present disclosure is not limited thereto. A chip-bonding region 111 is arranged approximately on a center portion of an upper surface 11 of the substrate 1, and the substrate 1 includes a plurality of first soldering pads 112 that are disposed on the upper surface 11 and are arranged outside of the chip-bonding region 111. The first soldering pads 112 in the present embodiment are substantially in a ring-shaped arrangement, but the present disclosure is not limited thereto. For example, in other embodiments of the present disclosure not shown in the drawings, the first soldering pads 112 can be arranged into two rows respectively at two opposite sides of the chip-bonding region 111.

In addition, a plurality of soldering balls (not labeled) can be further provided on a lower surface 12 of the substrate 1. The substrate 1 can be fixed and soldered onto an electronic component through the soldering balls, thereby electrically connecting the sensor package structure 100 to the electronic component.

The sensor chip 2 in the present embodiment is an image sensing chip, but the present disclosure is not limited thereto. The sensor chip 2 is fixed onto the chip-bonding region 111 of the substrate 1. In other words, the sensor chip 2 is located at inner sides of the first soldering pads 112. Moreover, a top surface 21 of the sensor chip 2 has a sensing region 211 and a plurality of second soldering pads 212 arranged outside of the sensing region 211.

Specifically, positions and a quantity of the second soldering pads 212 of the sensor chip 2 in the present embodiment correspond to those of the first soldering pads 112 of the substrate 1. Each of the wires 3 has two opposite ends, one end of each of the wires 3 is connected to one of the first soldering pads 112, and another end of each of the wires 3 is connected to one of the second soldering pads 212, so that the substrate 1 and the sensor chip 2 can be electrically coupled to each other through the wires 3.

The cover 4 in the present embodiment is disposed on the substrate 1 along an assembling direction D (perpendicular to the substrate 1), so that the sensor chip 2 and the wires 3 are arranged in a space surroundingly defined by the cover 4. In other words, the cover 4 and the substrate 1 jointly define an enclosed space E for allowing the sensor chip 2 and the wires 3 to be arranged therein.

Specifically, the cover 4 includes a light-permeable sheet 41, a light-shielding film 42, and an opaque frame 43. The light-permeable sheet 41 in the present embodiment is a transparent and flat glass board, and the light-permeable sheet 41 has an outer surface 411 and an inner surface 412, but the present disclosure is not limited thereto. For example, in other embodiments of the present disclosure not shown in the drawings, the light-permeable sheet 41 can be made of a light-permeable plastic material.

The light-shielding film 42 is in a ring-shape and opaque. The light-shielding film 42 is disposed on the inner surface 412 of the light-permeable sheet 41, so that the inner surface 412 is divided into a light-permeable region 4121 that is arranged inside of the light-shielding film 42 and a formation region 4122 that is arranged outside of the light-shielding film 42. Moreover, the opaque frame 43 is gaplessly formed on the formation region 4122 of the light-permeable sheet 41 (that is, the light-shielding film 42 is not embedded in the opaque frame 43), and the opaque frame 43 is disposed on the substrate 1 (and is arranged outside of the first soldering pads 112).

Accordingly, in the sensor package structure 100 of the present embodiment, the light-shielding film 42 is formed on the inner surface 412 of the light-permeable sheet 41. In this way, the light-permeable region 4121 of the inner surface 412 can be precisely defined, and the light-shielding film 42 can be configured to effectively prevent an external light from passing therethrough for avoiding a flare issue occurring. Moreover, formation of the opaque frame 43, the light-shielding film 42 can prevent the opaque frame 43 from flowing (or extending) toward the light-permeable region 4121, so that the opaque frame 43 can be precisely formed on the formation region 4122.

Preferably, the connection relationships of the cover 4 with respect to the sensor chip 2 and the wires 3 satisfy the following conditions, but the present disclosure is not limited thereto. A thickness of the light-shielding film 42 is less than a thickness of the light-permeable sheet 41, and is less than or equal to 40 μm. The sensing region 211 of the sensor chip 2 is arranged in a projection zone defined by orthogonally projecting the light-permeable region 4121 onto the top surface 21. Moreover, at least 90% volume of each of the wires 3 is located in a projection space defined by orthogonally projecting the light-shielding film 42 toward the substrate 1.

From another perspective, the opaque frame 43 has an inner side surface 431 and an outer side surface 432. The outer side surface 432 of the opaque frame 43 is coplanar with an outer side surface 413 of the light-permeable sheet 41, and is coplanar with an outer side 13 of the substrate 1. Moreover, a distance between the inner side surface 431 and the outer side surface 432 of the opaque frame 43 is decreased along a direction away from the light-permeable sheet 41 (that is, any one cross section of the opaque frame 43 perpendicular to the assembling direction D has an area that is less than or equal to an area of the formation region 4122), so that a part of each of the wires 3 is located in a projection space defined by orthogonally projecting the inner side surface 431 toward the substrate 1.

The above description describes the sensor package structure 100 of the present embodiment, and the following description describes the manufacturing method of the sensor package structure 100. It should be noted that the sensor package structure 100 in the present embodiment is produced by implementing the following manufacturing method, but the present disclosure is not limited thereto. For example, in other embodiments of the present disclosure not shown in the drawings, the sensor package structure 100 can be produced by adjusting steps of the following manufacturing method or can be produced by implementing other methods.

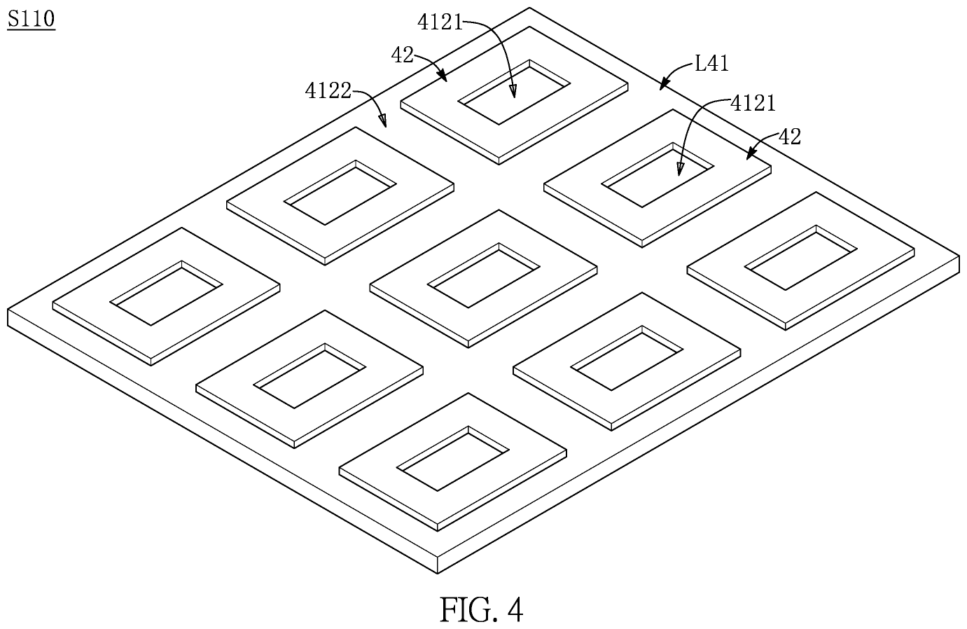

As shown in FIG. 4 to FIG. 8, preferably, the manufacturing method of the sensor package structure 100 in the present embodiment sequentially includes the following steps: a delimiting step S110, a molding step S120, a pre-cutting step S130, an encapsulating step S140, and a cutting step S150, but the present disclosure is not limited thereto. For example, in other embodiments of the present disclosure not shown in the drawings, the above steps S110 to S150 can be sequentially adjusted or can be added or canceled according to design requirements.

As shown in FIG. 4, the delimiting step S110 is implemented by forming multiple ones of the light-shielding film 42, that are spaced apart from each other, on an inner surface of a light-permeable layer L41 so as to divide the inner surface of the light-permeable layer L41 into a plurality of light-permeable regions 4121 arranged inside of the light-shielding films 42, respectively, and a formation region 4122 that is arranged outside of the light-shielding films 42.

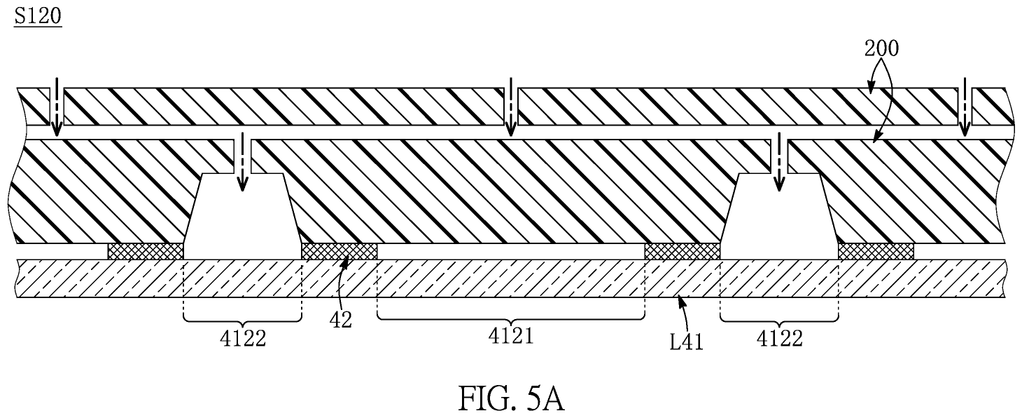

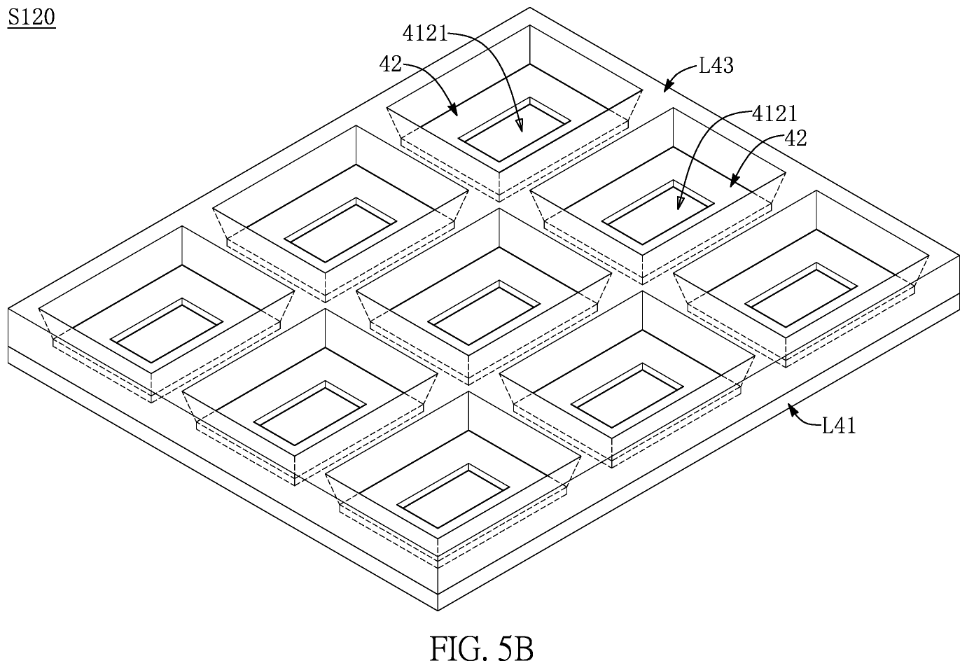

As shown in FIG. 5A and FIG. 5B, the molding step S120 is implemented by using a mold 200 to gaplessly press onto the light-shielding films 42, and then forming an opaque frame layer L43 on the formation region 4122 of the light-permeable layer L41. Specifically, the light-shielding films 42 (being resilient) are entirely pressed by the mold 200 and are resiliently deformed, such that the light-shielding films 42 are gaplessly connected to the mold 200 and not embedded in the opaque frame layer L43. Accordingly, during formation of the opaque frame layer L43, the opaque frame layer L43 cannot flow (or extend) toward the light-permeable region 4121 by passing through a gapless interface between the mold 200 and any one of the light-shielding films 42.

More specifically, as shown in FIG. 5A, a plastic material or an adhesive body (not shown in the drawings) in a melted mode can flow to the formation region 4122 of the light-permeable layer L41 along channels of the mold 200 (e.g., arrow symbols labeled in the mold 200 as shown in FIG. 5A). Then, the mold 200 is removed after the plastic material or the adhesive body is solidified, so that the opaque frame layer L43 can be formed on the formation region 4122 of the light-permeable layer L41 as shown in FIG. 5B.

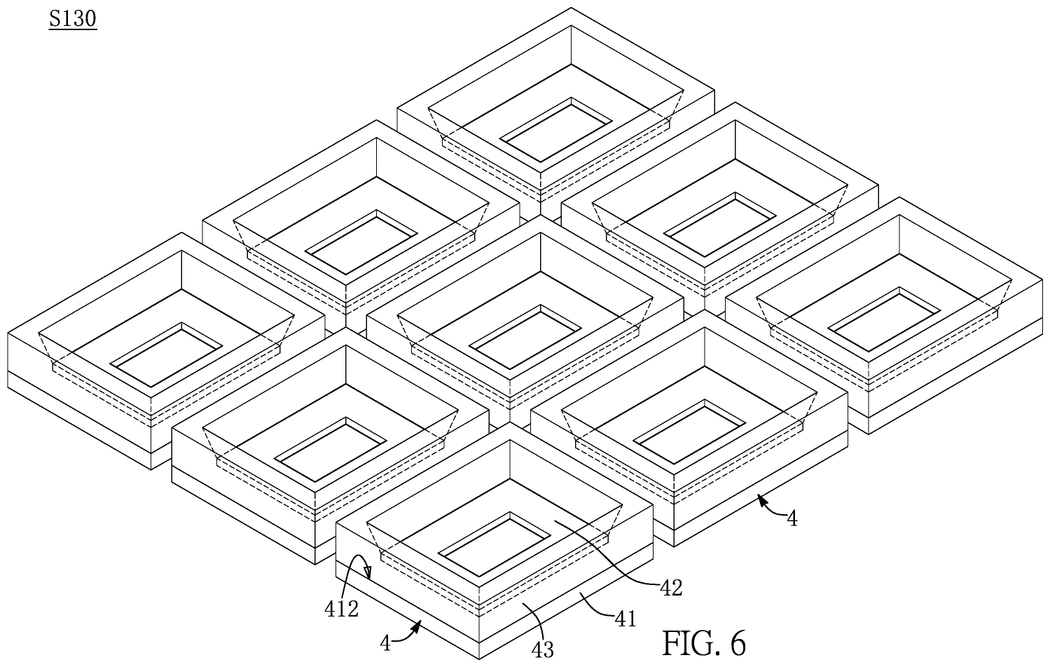

As shown in FIG. 5B and FIG. 6, the pre-cutting step S130 is implemented by cutting the light-permeable layer L41 and the opaque frame layer L43 to be divided into a plurality of covers 4. Specifically, the light-permeable layer L41 is cut into multiple ones of the light-permeable sheet 41, and the opaque frame layer L43 is cut into multiple ones of the opaque frame 43. The inner surface 412 of each of the light-permeable sheets 41 is formed with one of the light-shielding films 42 and one of the opaque frames 43, so as to be jointly defined as one of the covers 4.

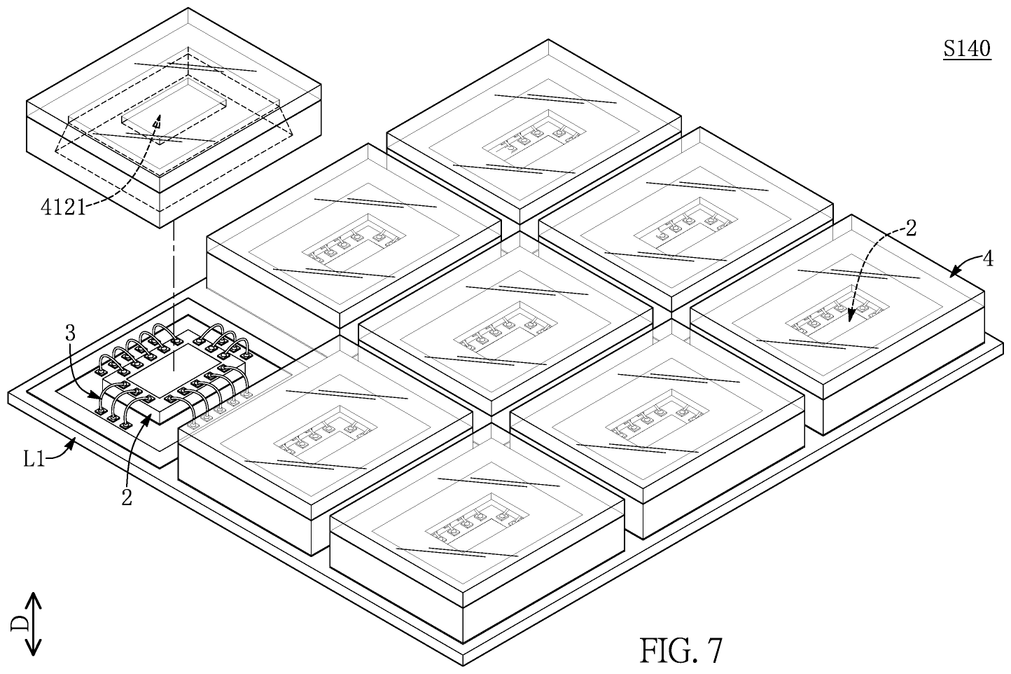

As shown in FIG. 7, the encapsulating step S140 is implemented by placing the covers 4 onto a substrate layer L1 that carries multiple ones of the sensor chip 2. Each of the covers 4 receives one of the sensor chips 2 therein, and each of the light-permeable regions 4121 faces toward a corresponding one of the sensor chips 2. Moreover, each of the sensor chips 2 can be electrically coupled to the substrate layer L1 through the wires 3, and the sensor chips 2 are not electrically coupled to each other.

Accordingly, the covers 4 in the present embodiment are assembled to corresponding portions of the substrate layer L1 one by one, so that a connection position between the substrate layer L1 and any one of the covers 4 can exhibit a high degree of accuracy, thereby meeting requirements of high-standard products.

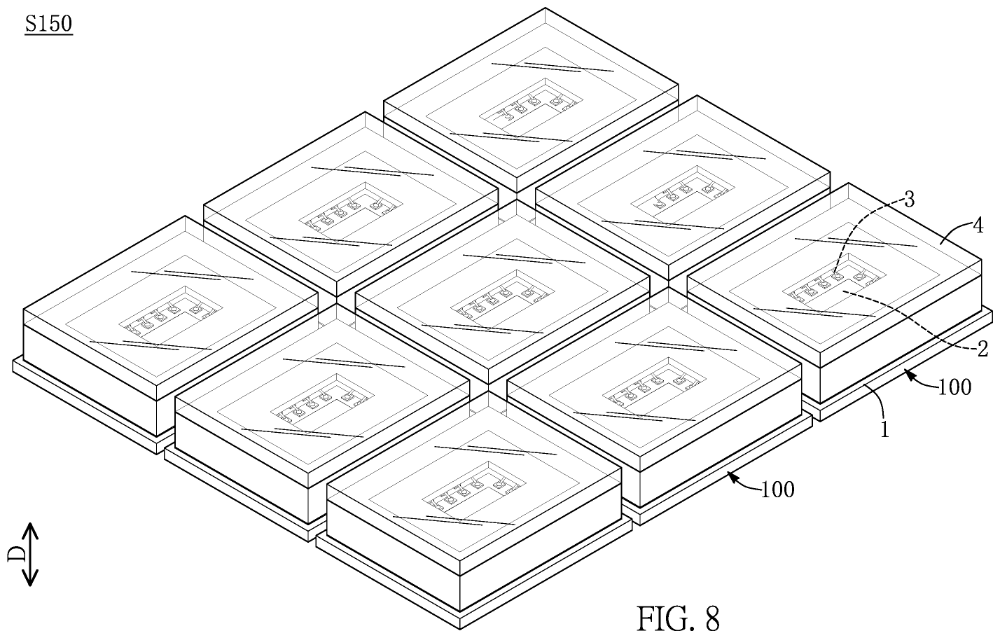

As shown in FIG. 7 and FIG. 8, the cutting step S140 is implemented by cutting the substrate layer L1 to be divided into a plurality of sensor package structures 100. Specifically, the substrate layer L1 is cut into multiple ones of the substrate 1. Each of the substrates 1 is formed with one of the sensor chips 2, corresponding ones of the wires 3, and one of the covers 4, so as to be jointly defined as one of the sensor package structures 100.

### Second Embodiment

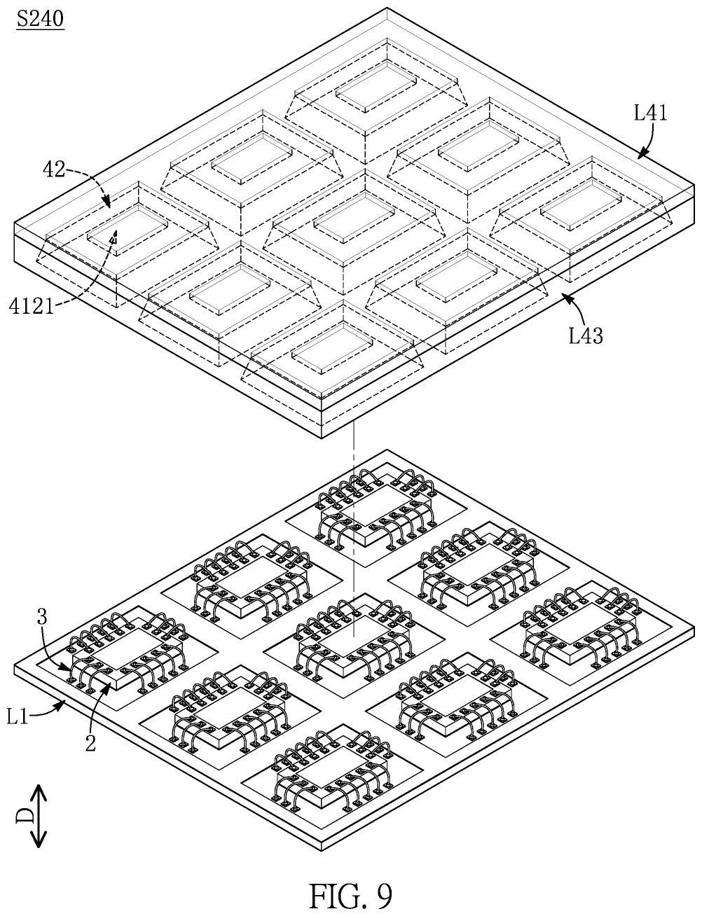

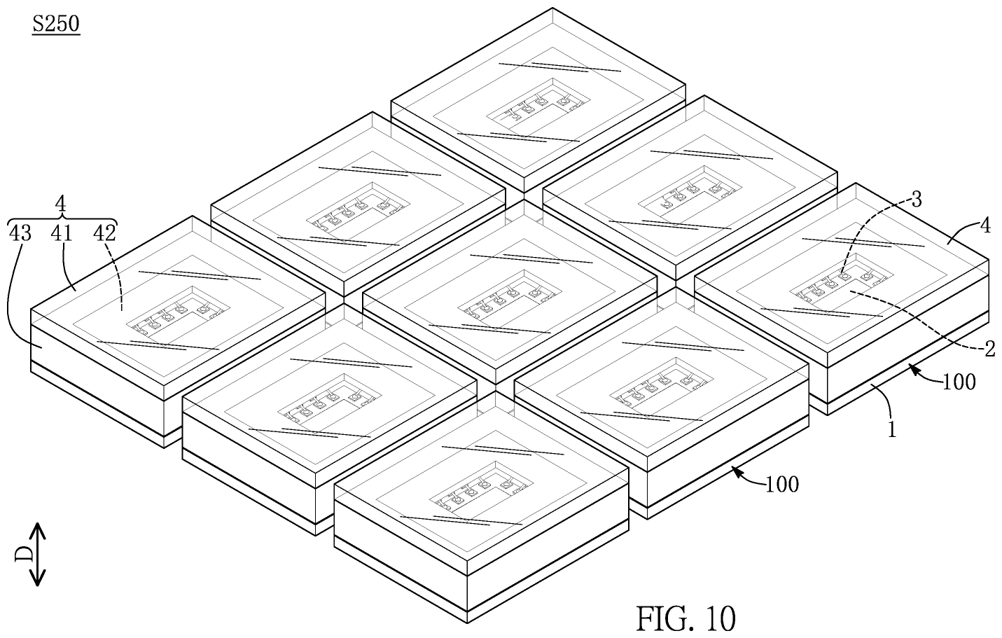

Referring to FIG. 9 and FIG. 10, a second embodiment of the present disclosure is provided, which is similar to the first embodiment of the present disclosure. For the sake of brevity, descriptions of the same components in the first and second embodiments of the present disclosure (e.g., the sensor package structure, the delimiting step, and the molding step) will be omitted herein, and the following description only discloses different features between the first and second embodiments.

The manufacturing method of the sensor package structure 100 in the present embodiment does not include the pre-cutting step S130 as disclosed in the first embodiment. In other words, in the manufacturing method of the sensor package structure 100 of the present embodiment, the molding step is followed by an encapsulating step S240 and a cutting step S250.

As shown in FIG. 9, the encapsulating step S240 is implemented by placing the opaque frame layer L43 onto the substrate layer L 1 that carries multiple ones of the sensor chip 2. Specifically, each of the light-permeable regions 4121 faces toward one of the sensor chips 2. Moreover, each of the sensor chips 2 can be electrically coupled to the substrate layer L1 through the wires 3, and the sensor chips 2 are not electrically coupled to each other.

Furthermore, the opaque frame layer L43 in the present embodiment is directly assembled onto the substrate layer L1 without being cut, so that the pre-cutting step S130 disclosed in the first embodiment can be omitted. Accordingly, the production process of the sensor package structure 100 can be effectively simplified, and the cost of manufacturing the sensor package structure 100 can be reduced.

As shown in FIG. 9 and FIG. 10, the cutting step S250 is implemented by cutting the light-permeable layer L41, the opaque frame layer L43, and the substrate layer 11 to be divided into a plurality of sensor package structures 100. Specifically, the light-permeable layer L41 is cut into multiple ones of the light-permeable sheet 41, and the opaque frame layer L43 is sliced into multiple ones of the opaque frame 43. The inner surface 412 of each of the light-permeable sheets 41 is formed with one of the light-shielding films 42 and one of the opaque frames 43, so as to be jointly defined as one of the covers 4. Moreover, the substrate layer L1 is sliced into multiple ones of the substrate 1. Each of the substrates 1 is formed with one of the sensor chips 2, corresponding ones of the wires 3, and one of the covers 4, so as to be jointly defined as one of the sensor package structures 100.

### Beneficial Effects of the Embodiments

In conclusion, in the sensor package structure and the manufacturing method thereof provided by the present disclosure, the light-shielding film is formed on the inner surface of the light-permeable sheet. In this way, the light-permeable region of the inner surface can be precisely defined, and external light can be effectively prevented from passing through the light-shielding film, so as to reduce occurrences of a flare issue. Moreover, during formation of the opaque frame, the light-shielding film can prevent the opaque frame from flowing toward the light-permeable region, so that the opaque frame can be precisely formed on the formation region.

Furthermore, the resilient light-shielding films can be entirely pressed by the mold, and the light-shielding films are resiliently deformed so as to be gaplessly connected to the mold. Accordingly, during formation of the opaque frame layer, the opaque frame layer cannot flow toward the light-permeable region by passing through the gapless interface between the mold and any one of the light-shielding films.

The foregoing description of the exemplary embodiments of the disclosure has been presented only for the purposes of illustration and description and is not intended to be exhaustive or to limit the disclosure to the precise forms disclosed. Many modifications and variations are possible in light of the above teaching.

The embodiments were chosen and described in order to explain the principles of the disclosure and their practical application so as to enable others skilled in the art to utilize the disclosure and various embodiments and with various modifications as are suited to the particular use contemplated. Alternative embodiments will become apparent to those skilled in the art to which the present disclosure pertains without departing from its spirit and scope.

What is claimed is:

1. A sensor package structure, comprising:
a substrate;
a sensor chip disposed on and electrically coupled to the substrate; and
a cover disposed on the substrate, wherein the sensor chip is arranged in a space surroundingly defined by the cover, and the cover includes:
a light-permeable sheet having an outer surface and an inner surface;
a light-shielding film being in a ring-shape and disposed on the inner surface, so that the inner surface is divided into a light-permeable region that is arranged inside of the light-shielding film and a formation region that is arranged outside of the light-shielding film; and
an opaque frame gaplessly formed on the formation region and disposed on the substrate, wherein the light-shielding film is not embedded in the opaque frame.

2. The sensor package structure according to claim 1, further comprising a plurality of wires electrically coupling the sensor chip to the substrate, wherein at least 90% of a volume of each of the wires is located in a projection space defined by orthogonally projecting the light-shielding film toward the substrate.

3. The sensor package structure according to claim 2, wherein the opaque frame has an inner side surface and an outer side surface, and wherein the outer side surface of the opaque frame is coplanar with an outer side surface of the light-permeable sheet and is coplanar with an outer side of the substrate.

4. The sensor package structure according to claim 3, wherein a distance between the inner side surface and the outer side surface of the opaque frame is decreased along a direction away from the light-permeable sheet, so that a part of each of the wires is located in a projection space defined by orthogonally projecting the inner side surface toward the substrate.

5. The sensor package structure according to claim 1, wherein a top surface of the sensor chip has a sensing region, and the sensing region is located in a projection zone defined by orthogonally projecting the light-permeable region onto the top surface.

6. The sensor package structure according to claim 1, wherein the cover is disposed on the substrate along an assembling direction, and wherein any one cross section of the opaque frame perpendicular to the assembling direction has an area that is less than or equal to an area of the formation region.

7. A manufacturing method of a sensor package structure, comprising:
implementing a delimiting step by forming a plurality of light-shielding films that are spaced apart from each other on an inner surface of a light-permeable layer, so as to divide the inner surface of the light-permeable layer into a plurality of light-permeable regions respectively arranged inside of the light-shielding films and a formation region that is arranged outside of the light-shielding films;
implementing a molding step by using a mold to gaplessly press onto the light-shielding films, and then forming an opaque frame layer on the formation region of the light-permeable layer;
implementing a pre-cutting step by cutting the light-permeable layer and the opaque frame layer, so as to form a plurality of covers;
implementing an encapsulating step by placing the covers onto a substrate layer that carries a plurality of sensor chips, wherein each of the covers encloses one of the sensor chips therein, and each of the light-permeable regions faces toward one of the sensor chips; and
implementing a cutting step by cutting the substrate layer, so as to form multiple ones of the sensor package structure.

8. The manufacturing method according to claim 7, wherein in the molding step, the light-shielding films are entirely pressed by the mold and are resiliently deformed, such that the light-shielding films are gaplessly connected to the mold and not embedded in the opaque frame layer.

9. A manufacturing method of a sensor package structure, comprising:
implementing a delimiting step by forming a plurality of light-shielding films that are spaced apart from each other on an inner surface of a light-permeable layer, so as to divide the inner surface of the light-permeable layer into a plurality of light-permeable regions respectively arranged inside of the light-shielding films respectively and a formation region that is arranged outside of the light-shielding films;
implementing a molding step by using a mold to gaplessly press onto the light-shielding films, and then forming an opaque frame layer on the formation region of the light-permeable layer;
implementing an encapsulating step by placing the opaque frame layer onto a substrate layer that carries a plurality of sensor chips, wherein each of the light-permeable regions faces toward one of the sensor chips; and
implementing a cutting step by cutting the light-permeable layer, the opaque frame layer, and the substrate layer, so as to form multiple ones of the sensor package structure.

10. The manufacturing method according to claim 9, wherein in the molding step, the light-shielding films are entirely pressed by the mold and are resiliently deformed, such that the light-shielding films are gaplessly connected to the mold and not embedded in the opaque frame layer.
